(19) United States
(12) Patent Application Publication
(10) Pub. No.: US 2025/0374621 A1
(43) Pub. Date: Dec. 4, 2025

(54) SEMICONDUCTOR DEVICE AND METHOD FOR FABRICATING THE SAME

(71) Applicant: SK hynix Inc., Gyeonggi-do (KR)

(72) Inventor: Seung Hwan KIM, Gyeonggi-do (KR)

(21) Appl. No.: 18/983,386

(22) Filed: Dec. 17, 2024

(30) Foreign Application Priority Data
May 31, 2024 (KR) 10-2024-0071681

(51) Int. Cl. H10D 62/10; H01L 21/02; H01L 21/762

(52) U.S. Cl. CPC H10D 62/126; H01L 21/02532; H01L 21/762

(57) ABSTRACT

A semiconductor device may include a substrate; an active region disposed over the substrate; a buried layer disposed between the substrate and the active region; an isolation structure surrounding a bottom surface and side surfaces of the active region and surrounding side surfaces of the buried layer; a gate trench formed in the active region; a gate dielectric layer formed on the gate trench; and a gate electrode disposed on the gate dielectric layer and partially filling the gate trench.

### CROSS-REFERENCE TO RELATED APPLICATIONS

The present application claims priority under 35 U.S.C 119(a) to Korean Patent Application No. 10-2024-0071681, filed on May 31, 2024, which is incorporated herein by reference in its entirety.

### BACKGROUND

### 1. Field

Various embodiments of the present disclosure relate to a semiconductor device, and more particularly, to a semiconductor device including an isolation structure, and a method for fabricating the semiconductor device.

### 2. Description of the Related Art

As semiconductor devices become more highly integrated, it becomes increasingly difficult to electrically isolate a plurality of semiconductor structures. Also, as the space between a plurality of active regions is decreasing leakage may increase significantly. Hence new methods, materials etc. which can improve the electrical isolation of the various semiconductor structures and reduce leakage current are needed.

### SUMMARY

Embodiments of the present disclosure are directed to a semiconductor device having improved electrical characteristics, and a method for fabricating the semiconductor device.

In accordance with an embodiment of the present disclosure, a semiconductor device may include: a substrate; an active region disposed over the substrate; a buried layer disposed between the substrate and the active region; and an isolation structure surrounding a bottom surface and side surfaces of the active region and surrounding side surfaces of the buried layer.

In accordance with an embodiment of the present disclosure, a semiconductor device may include: a substrate; an active region disposed over the substrate; a buried layer disposed between the substrate and the active region; an isolation structure surrounding a bottom surface and side surfaces of the active region and surrounding side surfaces of the buried layer; a gate trench formed in the active region; a gate dielectric layer formed on the gate trench; and a gate electrode disposed on the gate dielectric layer and partially filling the gate trench.

In accordance with an embodiment of the present disclosure, a method for fabricating a semiconductor device may include: stacking a buried material layer and an active layer on a substrate; etching the active layer and forming line-shape openings and a line-shape active layer; etching the buried material layer below the line-shape openings and forming a line-shape buried layer; forming line-shape isolation layers that fill the line-shape openings; etching the line-shape active layer and forming an active region and hole-shape openings; forming undercuts between the active region and the substrate while forming a buried layer by etching the line-shape buried layer from the hole-shape openings; and forming pillar-shape isolation layers that fill the undercuts and the hole-shape openings.

These and other features and advantages of the present invention will become apparent to those skilled in the art of the invention from the following detailed description in conjunction with the following drawings.

### BRIEF DESCRIPTION OF THE DRAWINGS

FIG. 1A is a schematic plan view illustrating a semiconductor device in accordance with an embodiment of the present disclosure.

FIG. 1B is a cross-sectional view illustrating the semiconductor device taken along line A-A′ shown in FIG. 1A.

FIG. 1C is a schematic plan view illustrating the semiconductor device taken along line A1-A1′ shown in FIG. 1B.

FIG. 1D is a schematic plan view illustrating the semiconductor device taken along line A2-A2′ shown in FIG. 1B.

FIG. 1E is a view illustrating a data storage element illustrated in FIG. 1B.

FIG. 2A to 11B illustrate various views of a semiconductor device formed utilizing a method for fabricating the semiconductor device in accordance with an embodiment of the present disclosure.

FIGS. 12 and 13 are views illustrating a semiconductor device in accordance with another embodiment of the present disclosure.

### DETAILED DESCRIPTION

Various embodiments may be described herein with reference to cross-sectional views, plan views and block diagrams, which are ideal schematic views of a semiconductor device. It is noted that the structures of the drawings may be modified by fabricating techniques and/or tolerances. The present disclosure is not limited to the described embodiments and the specific structures illustrated in the drawings, but may include other embodiments, or modifications of the described embodiments including any changes in the structures that may be produced according to requirements of the fabricating process. Accordingly, the regions illustrated in the drawings have schematic attributes, and the shapes of the regions illustrated in the drawings are intended to illustrate specific structures of regions of the elements, and are not intended to limit the scope of the disclosure.

In the described embodiments, a semiconductor device may include a buried channel array transistor (BCAT) which includes a gate electrode buried in a gate trench for minimizing a short channel effect.

The buried channel array transistor may include a buried gate structure, and the buried gate structure may include a stack of a gate trench, a gate dielectric layer, a gate electrode, and a capping layer. The gate dielectric layer may cover a surface of the gate trench, the gate electrode may partially fill the gate trench on the gate dielectric layer, and the capping layer may fill the remainder of the gate trench on the gate electrode. Accordingly, the gate electrode may be referred to as a “buried gate electrode”.

The gate electrode may include a single gate or a dual gate. The single gate may refer to a gate formed of polysilicon or a metal-based material. The single gate may include a polysilicon single gate or a metal single gate. The dual gate may refer to a bilayer stack of different gate materials. The dual gate may include a same-metal dual gate formed of a stack of the same metal, a dissimilar-metal dual gate formed of a stack of different metals, or a dissimilar-material dual gate formed of a stack of metal and polysilicon.

The gate electrode may include a barrier layer and a low-resistance material. The barrier layer may serve to block dopants diffusing from the low-resistance material or to prevent mutual diffusion and reaction between different materials. The low-resistance material may serve to reduce sheet resistance of the gate electrode.

The gate electrode may include a material whose work function is engineered. Work function engineering may refer to a material or method capable of adjusting the work function so as to have a reduced work function, i.e., a low work function, or an increased work function, i.e., a high work function.

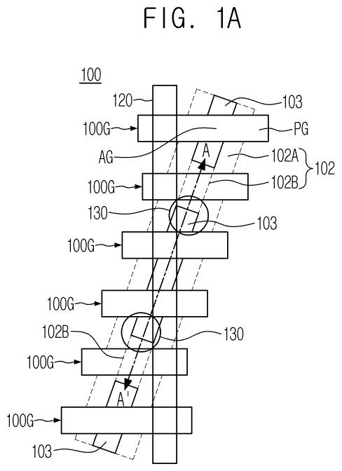

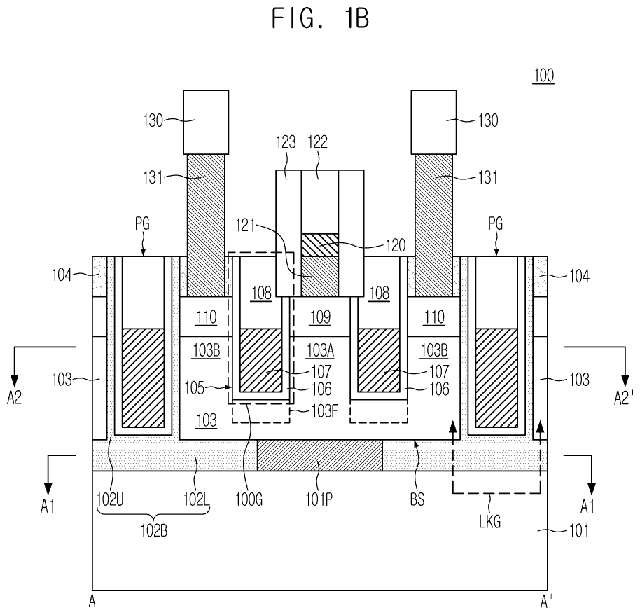

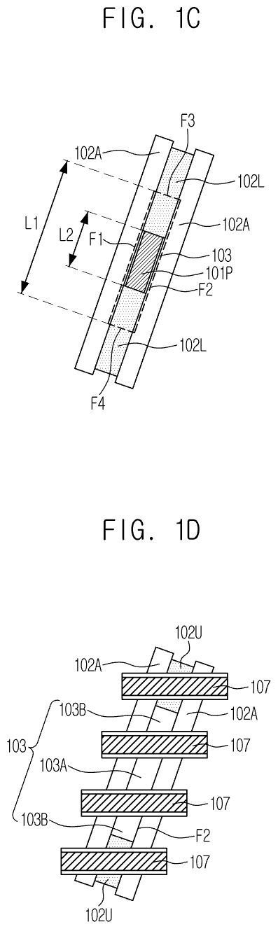

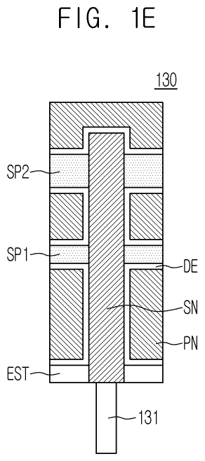

FIG. 1A is a schematic plan view illustrating a semiconductor device 100 in accordance with an embodiment of the present disclosure. FIG. 1B is a cross-sectional view illustrating the semiconductor device 100 taken along line A-A′ shown in FIG. 1A. FIG. 1C is a schematic plan view illustrating the semiconductor device 100 taken along line A1-A1′ shown in FIG. 1B. FIG. 1D is a schematic plan view illustrating the semiconductor device 100 taken along line A2-A2′ shown in FIG. 1B.

Referring to FIGS. 1A to 1D, the semiconductor device 100 may include a substrate 101, an isolation structure 102, an active region 103 defined by the isolation structure 102, a buried layer 101P disposed between the substrate 101 and the active region 103, and a buried gate structure 100G.

The active region 103 may be formed on the substrate 101, and the buried layer 101P may be disposed between the substrate 101 and the active region 103. The substrate 101, the buried layer 101P, and the active region 103 may each include a semiconductor material. The substrate 101 and the active region 103 may be the same semiconductor material. The buried layer 101P and the substrate 101 may be different semiconductor materials. The buried layer 101P and the active region 103 may be different semiconductor materials.

The substrate 101 may be a material suitable for semiconductor processing. The substrate 101 may include a semiconductor substrate. The substrate 101 may be formed of a material containing silicon. The substrate 101 and the active region 103 may each include silicon, monocrystalline silicon, polysilicon, amorphous silicon, carbon-doped silicon, a combination thereof, or a multilayer thereof. The buried layer 101P may be a material having an etch selectivity with respect to the substrate 101 and the active region 103. The buried layer 101P may include germanium-containing silicon, boron-containing silicon, or a combination thereof. The buried layer 101P may include silicon germanium (SiGe) or silicon boron nitride (SiBN). The buried layer 101P and the active region 103 may be formed by epitaxial growth on the substrate 101. In another embodiment, the active region 103 may include an oxide semiconductor material such as IGZO (InGaZnO).

A horizontal length L1 of the active region 103 may be greater than a horizontal length L2 of the buried layer 101P.

The active region 103 may be defined by the isolation structure 102. The isolation structure 102 may include first isolation structures 102A and second isolation structures 102B. The first isolation structures 102A may each have a line shape. The second isolation structures 102B may each have a pillar shape. The first and second isolation structures 102A and 102B may each include a dielectric material. The first and second isolation structures 102A and 120B may each include a dielectric material including silicon oxide, silicon nitride, an embedded air gap, or a combination thereof. The isolation structure 102 may have a shape of surrounding side surfaces and bottom surface of the active region 103. The isolation structure 102 may have a shape of surrounding side surfaces of the buried layer 101P.

Each of the second isolation structures 102B may include a buried isolation portion 102L and a pillar isolation portion 102U. The buried isolation portion 102L may extend horizontally from a bottom surface of the pillar isolation portion 102U. The pillar isolation portion 102U and the buried isolation portion 102L may be the same material and may have an integral structure. The second isolation structure 102B may have a “L” shape formed by a combination of the pillar isolation portion 102U and the buried isolation portion 102L. The pillar isolation portion 102U and the buried isolation portion 102L may each include a dielectric material including silicon oxide, silicon nitride, an air gap, and an embedded air gap, or a combination thereof. Since the isolation structure 102 includes a combination of the first isolation structures 102A and the second isolation structures 102B, the isolation structure 102 may be referred to as a “hybrid isolation structure”.

The active region 103 may include a plurality of side wall facets F1 to F4 and a bottom surface BS. The side wall facets F1 to F4 may include first side wall facets F1 and F2 and second side wall facets F3 and F4. The first side wall facets F1 and F2 may contact the first isolation structures 102A. The second side wall facets F3 and F4 may contact the second isolation structures 102B. The surface area of the first side wall facets F1 and F2 may be larger than that of the second side wall facets F3 and F4. The bottom surface BS of the active region 103 may contact the second isolation structures 102B. The bottom surface BS of the active region 103 may contact the buried isolation portions 102L of the second isolation structures 102B. The buried isolation portions 102L may contact the buried layer 101P.

Gate trenches 105 may be formed in the active region 103. The gate trenches 105 may each have a line shape extending in one direction. The gate trenches 105 may each have a line shape crossing the active region 103 and the first isolation structure 102A. The gate trenches 105 and the buried layer 101P may be spaced apart from each other. In another embodiment (not shown), bottom surfaces of the gate trenches 105 may each have a curvature.

The gate trenches 105 may be formed to have a portion formed in the isolation structure 102 deeper than a portion formed in the active region 103. For example, portions of the first isolation structures 102A may be recessed below the gate trenches 105. Accordingly, a fin region 103F may be formed below each of the gate trenches 105. The fin region 103F may be a region where a portion of a channel is formed, and be referred to as a saddle fin. A channel width may be increased by the fin region 103F, and electrical characteristics may be improved.

Two gate trenches 105 may be disposed in one active region 103. A portion of the active region 103 may be divided into one first active node 103A and two second active nodes 103B by the gate trenches 105. The first active node 103A may be disposed between the two second active nodes 103B. The buried isolation portions 102L of the second isolation structures 102B may be disposed below the second active nodes 103B. The buried layer 101P may be disposed below the first active node 103A.

A first doped region 109 and a second doped region 110 may be formed in the active region 103. The first doped region 109 and the second doped region 110 are regions doped with a conductive dopant. For example, the conductive dopant may include phosphorus (P), arsenic (As), antimony (Sb), or boron (B). The first doped region 109 and the second doped region 110 may be doped with the same conductive type of a dopant. The first doped region 109 may be formed in the first active node 103A, and the second doped region 110 may be formed in the second active nodes 103B. The first doped region 109 and the second doped region 110 may contact side walls of the gate trench 105. Bottom surfaces of the first doped region 109 and the second doped region 110 may be higher than the bottom surface of the gate trench 105. The first doped region 109 may be referred to as a “first source/drain region”, and the second doped region 110 may be referred to as a “second source/drain region”. The channel may be defined along the profile of the gate trench 105 between the first doped region 109 and the second doped region 110 by the buried gate structure 100G. A depth of the first doped region 109 may be the same as or different from that of the second doped region 110.

The buried gate structure 100G may include a gate dielectric layer 106 covering the bottom surface and side walls of the gate trench 105, a gate electrode 107 disposed on the gate dielectric layer 106 and partially filling the gate trench 105, and a capping layer 108 disposed on the gate electrode 107 to fill a remainder of the gate trench 105. A combination of the gate electrode 107, the first doped region 109 and the second doped region 110 may constitute a cell transistor. The buried gate structure 100G may include an active gate AG disposed in the active region 103 and a passing gate PG disposed in the isolation structure 102. The passing gate PG may be disposed in the first isolation structure 102A.

The gate dielectric layer 106 may include a high-k material, oxide, nitride, oxynitride, or a combination thereof. The high-k material may include a hafnium-containing material. The hafnium-containing material may include hafnium oxide, hafnium silicon oxide, hafnium silicon oxynitride, or a combination thereof. In another embodiment, the high-k material may include lanthanum oxide, lanthanum aluminum oxide, zirconium oxide, zirconium silicon oxide, zirconium silicon oxynitride, aluminum oxide, or a combination thereof. Other publicly-known high-k materials may selectively be used as the high-k material. In another embodiment, the gate dielectric layer 106 may include a stack of silicon oxide and a high-k material. The silicon oxide may be formed on a surface of the gate trench 105, and the high-k material may be formed on the silicon oxide. The high-k material may include a material having a higher areal density of oxygen atom than the silicon oxide.

The gate electrode 107 may be a buried gate electrode that partially fills the gate trench 105. The gate electrode 107 may be positioned at a level lower than the top surface of the active region 103, that is, the top surfaces of the first and second doped regions 109 and 110. The gate electrode 107 may include a semiconductor material, a metal, a metal-based material, or a combination thereof. The gate electrode 107 may include metal, metal nitride, or a combination thereof. The gate electrode 107 may include polysilicon, tantalum nitride (TaN), titanium nitride (TiN), tungsten (W), tungsten nitride (WN), molybdenum (Mo), ruthenium (Ru), or a combination thereof. The gate electrode 107 may be formed only of titanium nitride. In another embodiment, the gate electrode 107 may have a high work function. The high work function refers to a work function higher than a mid-gap work function of silicon. A low work function refers to a work function lower than the mid-gap work function of silicon. Specifically, the high work function may be higher than 4.5 eV, and the low work function may be lower than 4.5 eV. The gate electrode 107 may include P-type polysilicon or nitrogen-rich titanium nitride (TiN).

In another embodiment, the gate electrode 107 may have an increased high work function. The gate electrode 107 may include metal silicon nitride. The metal silicon nitride may be metal nitride doped with silicon. The gate electrode 107 may include metal silicon nitride having an adjusted atomic percent of silicon. For example, the gate electrode 107 may include tantalum silicon nitride (TaSiN) or titanium silicon nitride (TiSiN). Titanium nitride may have a high work function, and contain silicon to further increase the work function thereof. The titanium silicon nitride may have an adjusted atomic percent of silicon, so as to have an increased high work function. In another embodiment, the gate electrode 107 may include titanium aluminum nitride (TiAlN).

The capping layer 108 may serve to protect the gate electrode 107. The capping layer 108 may fill an upper portion of the gate trench 105 on the gate electrode 107. A top surface of the capping layer 108 may be positioned at the same level as the top surfaces of the first and second doped regions 109 and 110.

A bit line 120 may be electrically connected to the first doped region 109. For example, the bit line 120 may be connected to the first doped region 109 through a first contact node 121. A data storage element 130 may be electrically connected to the second doped region 110. For example, the data storage element 130 may be connected to the second doped region 110 through a second contact node 131. The first contact node 121 may be referred to as a “bit line contact plug”, and the second contact node 131 may be referred to as a “storage contact plug”.

The first and second contact nodes 121 and 131 may each include a semiconductor material, a doped semiconductor material, a metal, a metal-based material, a metal-nitride-based material, conductive metal oxide, or a combination thereof. For example, the first contact node 121 may include doped polysilicon, and the second contact node 131 may include a stack structure of polysilicon, titanium nitride, and tungsten.

The bit line 120 may include a semiconductor material, a doped semiconductor material, a metal, a metal-based material, a metal-nitride-based material, conductive metal oxide, or a combination thereof. For example, the bit line 120 may include a stack structure of titanium nitride and tungsten. A bit line hard mask layer 122 may be formed on the bit line 120, and a bit line spacer 123 may be formed on a side wall of the bit line 120. The bit line spacer 123 may extend to cover side walls of the bit line hard mask layer 122 and first contact node 121. The bit line hard mask layer 122 may include silicon nitride, silicon oxide, or a combination thereof. The bit line spacer 123 may include silicon nitride, silicon oxide, a low-k material, an air gap, or a combination thereof. The low-k material may include silicon carbon oxide (SiCO), SiBN, SiBCN, or a combination thereof.

The data storage element 130 may include a memory element such as a capacitor.

FIG. 1E is a view illustrating the data storage element 130 illustrated in FIG. 1B.

Referring to FIG. 1E, the data storage element 130 may include a first electrode SN, a second electrode PN, and a dielectric layer DE between the first electrode SN and the second electrode PN. The first electrode SN may have a pillar shape. In another embodiment, the first electrode SN may have a cylinder shape, a flat plate shape, or a pylinder shape. The pylinder shape may refer to a structure in which the pillar shape and the cylinder shape are merged.

An outer wall of the first electrode SN of the data storage element 130 may be supported by multilayer level supporters SP1 and SP2. The multilayer level supporters SP1 and SP2 may include a dielectric material, for example, silicon nitride, silicon carbon nitride, or a combination thereof. In another embodiment, the multilayer level supporters may include three or more supporters. A bottom portion of the first electrode SN of the data storage element 130 may be supported by an etch stop layer EST. The etch stop layer EST may include silicon nitride, silicon carbon nitride, or a combination thereof. The bottom portion of the first electrode SN of the data storage element 130 may penetrate the etch stop layer EST and may be connected to the second contact node 131.

The first electrode SN and the second electrode PN of the data storage element 130 may include metal, noble metal, metal nitride, conductive metal oxide, conductive noble metal oxide, metal carbide, metal silicide, or a combination thereof. For example, the first electrode SN and the second electrode PN may each include titanium (Ti), titanium nitride (TIN), tantalum (Ta), tantalum nitride (TaN), tungsten (W), tungsten nitride (WN), ruthenium (Ru), ruthenium oxide (RuO₂), iridium (Ir), iridium oxide (IrO₂), platinum (Pt), molybdenum (Mo), molybdenum oxide (MoO), a stack of titanium nitride/tungsten (TiN/W), a stack of tungsten nitride/tungsten (WN/W), or a combination thereof. The second electrode PN may also include a combination of a metal-based material and a silicon-based material. For example, the second electrode PN may be a stack of titanium nitride/silicon germanium/tungsten nitride (TiN/SiGe/WN). In the stack of titanium nitride/silicon germanium/tungsten nitride (TiN/SiGe/WN), the silicon germanium (SiGe) may be a gap-fill material filling the inner side of the first electrode SN, the titanium nitride (TiN) may serve as the second electrode PN of the data storage element 130, and the tungsten nitride (WN) may be a low-resistivity material.

The dielectric layer DE may be referred to as a capacitor dielectric layer or a memory layer. The dielectric layer DE may include silicon oxide, silicon nitride, a high-k material, a perovskite material, or a combination thereof. The high-k material may include hafnium oxide (HfO₂), zirconium oxide (ZrO₂), aluminum oxide (Al₂O₃), lanthanum oxide (La₂O₃), titanium oxide (TiO₂), tantalum oxide (Ta₂O₅), niobium oxide (Nb₂O₅), or strontium titanium oxide (SrTiO₃). In another embodiment, the dielectric layer DE may be formed of a composite layer including two or more layers of the above-described high-k material.

The dielectric layer DE may be formed of zirconium-based oxide. The dielectric layer DE may have a stack structure containing zirconium oxide (ZrO₂). The dielectric layer DE may include a ZA (ZrO₂/Al₂O₃) stack or a ZAZ (ZrO₂/Al₂O₃/ZrO₂) stack. The ZA stack may have a structure in which aluminum oxide (Al₂O₃) is stacked on zirconium oxide (ZrO₂). The ZAZ stack may have a structure in which zirconium oxide (ZrO₂), aluminum oxide (Al₂O₃), and zirconium oxide (ZrO₂) are sequentially stacked. The ZA stack and the ZAZ stack may be referred to as a zirconium oxide-based layer (ZrO₂-based layer). In another embodiment, the dielectric layer DE may be formed of hafnium-based oxide (Hf-based oxide). The dielectric layer DE may be a stack structure containing hafnium oxide (HfO₂). The dielectric layer DE may include an HA (HfO₂/Al₂O₃) stack or an HAH (HfO₂/Al₂O₃/HfO₂) stack. The HA stack may have a structure in which aluminum oxide (Al₂O₃) is stacked on hafnium oxide (HfO₂). The HAH stack may have a structure in which hafnium oxide (HfO₂), aluminum oxide (Al₂O₃), and hafnium oxide (HfO₂) are sequentially stacked. The HA stack and the HAH stack may be referred to as a hafnium oxide-based layer (HfO₂-based layer). In the ZA stack, ZAZ stack, HA stack, and HAH stack, aluminum oxide (Al₂O₃) may have a greater band gap energy than zirconium oxide (ZrO₂) and hafnium oxide (HfO₂). Aluminum oxide (Al₂O₃) may have a lower dielectric constant than zirconium oxide (ZrO₂) and hafnium oxide (HfO₂). Accordingly, the dielectric layer DE may include a stack of a high-k material and a high band gap material that has a greater band gap energy than the high-k material. The dielectric layer DE may include silicon oxide (SiO₂) as a high band gap material other than aluminum oxide (Al₂O₃). Leakage current may be suppressed by containing a high band gap material in the dielectric layer DE. The high band gap material may be thinner than the high-k material. In another embodiment, the dielectric layer DE may include a stack structure in which a high-k material and a high band gap material are alternately stacked. For example, the dielectric layer DE may include a ZAZA (ZrO₂/Al₂O₃/ZrO₂/Al₂O₃) stack, a ZAZAZ (ZrO₂/Al₂O₃/ZrO₂/Al₂O₃/ZrO₂) stack, a HZAZH (HfO₂/ZrO₂/Al₂O₃/ZrO₂/HfO₂) stack, a HAHA (HfO₂/Al₂O₃/HfO₂/Al₂O₃) stack, or a HAHAH (HfO₂/Al₂O₃/HfO₂/Al₂O₃/HfO₂) stack. In the above stack structures, aluminum oxide (Al₂O₃) may be thinner than zirconium oxide (ZrO₂) and hafnium oxide (HfO₂).

In another embodiment, the dielectric layer DE may include a high-k material and a high band gap material. The dielectric layer DE may have a laminated structure in which a plurality of high-k materials and a plurality of high band gap materials are stacked, or a mixed structure in which a high-k material and a high band gap material are intermixed.

In another embodiment, the dielectric layer DE may include a ferroelectric material, an anti-ferroelectric material, or a combination thereof. For example, the dielectric layer DE may include HfZrO.

In another embodiment, the dielectric layer DE may include a combination of a high-k material and a ferroelectric material, a combination of a high-k material and an anti-ferroelectric material, or a combination of a high-k material or a ferroelectric material and an anti-ferroelectric material.

In another embodiment, an interface control layer may be further formed between the first electrode SN and the dielectric layer DE to improve leakage current (i.e., reduce leakage current). The interface control layer may include titanium oxide (TiO₂), tantalum oxide (Ta₂O₅), niobium oxide (Nb₂O₅), niobium nitride (NbN), or a combination thereof. The interface control layer may also be formed between the second electrode PN and the dielectric layer DE.

In other embodiments, the data storage element 130 may be a thyristor, a phase-change material, a Magnetic Tunnel Junction (MTJ), or a variable resistance material.

According to the above-described FIGS. 1A to 1E, the semiconductor device 100 may include the isolation structure 102 and the buried layer 101P, and leakage current may be suppressed by the second isolation structure 102B of the isolation structure 102. In addition, the depth of the isolation structure 102 may be reduced by the second isolation structure 102B. Even though the aspect ratio of the active region 103 increases in response to high integration of the semiconductor device 100, leaning of the active region 103 may be prevented by the second isolation structure 102B.

In addition, since the buried isolation portions 102L of the second isolation structure 102B are disposed below the second active nodes 103B, a leakage current path (refer to reference symbol “LKG” of FIG. 1B) between neighboring active regions 103 may be reduced significantly or blocked.

Moreover, the depth of the gate trench 105 may be increased by the buried isolation portions 102L of the second isolation structure 102B, and thus a cell threshold voltage may be increased. Consequently, as threshold voltage ion implantation dose is reduced due to a threshold voltage increasing effect, refresh time (tREF) may be improved.

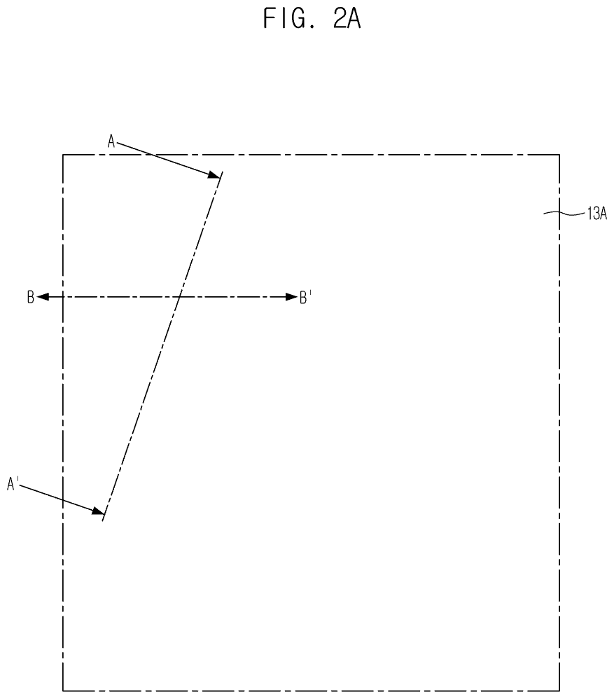

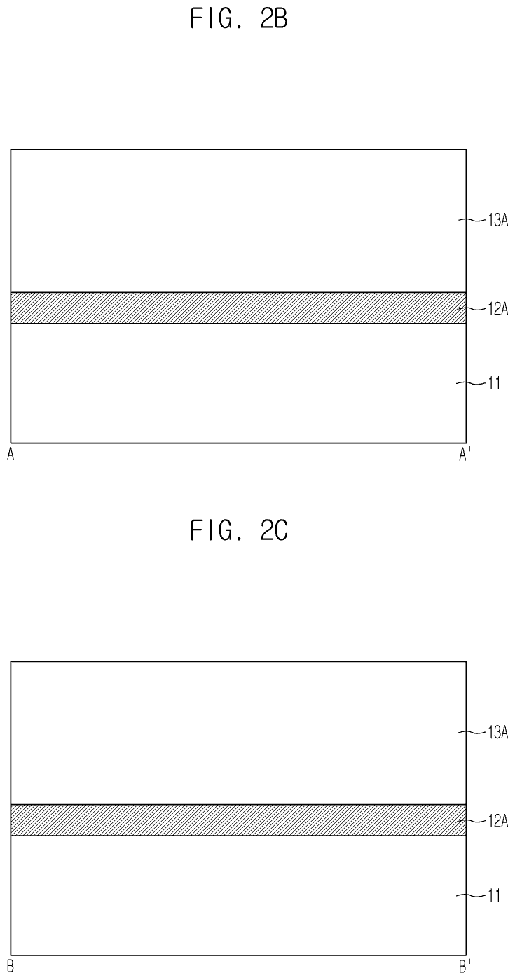

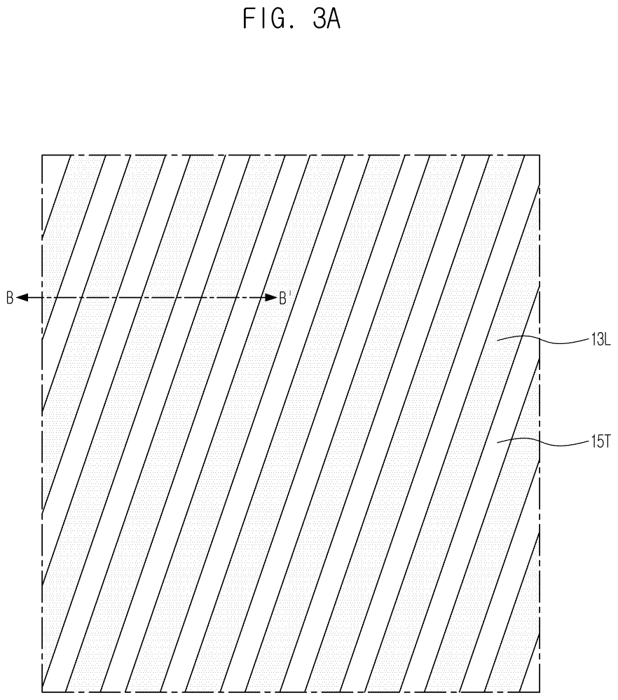

FIG. 2A to 11B illustrate various views of a semiconductor device formed utilizing a method for fabricating the semiconductor device in accordance with an embodiment of the present disclosure.

FIG. 2A is a plan view illustrating the semiconductor device to describe a method for forming an active layer 13A, FIG. 2B is a cross-sectional view illustrating the semiconductor device taken along line A-A′ shown in FIG. 2A, and FIG. 2C is a cross-sectional view illustrating the semiconductor device taken along line B-B′ shown in FIG. 2A.

As illustrated in FIGS. 2A to 2C, a buried material layer 12A may be formed on a substrate 11. The active layer 13A may be formed on the buried material layer 12A.

The substrate 11 may be a material suitable for semiconductor processing. The substrate 11 and the active layer 13A may each be formed of a silicon-containing material. The substrate 11 and the active layer 13A may each include silicon, monocrystalline silicon, polysilicon, amorphous silicon, carbon-doped silicon, a combination thereof or a multi-layer thereof. The substrate 11 and the active layer 13A may be the same material. The buried material layer 12A may be a material having an etch selectivity with respect to the substrate 11 and the active layer 13A. The buried material layer 12A may include germanium-containing silicon, boron-containing silicon, or a combination thereof. The buried material layer 12A may include silicon germanium (SiGe) or silicon boron nitride (SiBN). The buried material layer 12A and the active layer 13A may be formed by epitaxial growth on or over the substrate 11. The buried material layer 12A may be formed by epitaxial growth on the substrate 11. The active layer 13A may be formed by epitaxial growth on the buried material layer 12A. In another embodiment, the active layer 13A may include an oxide semiconductor material such as IGZO (InGaZnO). In another embodiment, the buried material layer 12A and the active layer 13A may be formed by a deposition method such as chemical vapor deposition or atomic layer deposition.

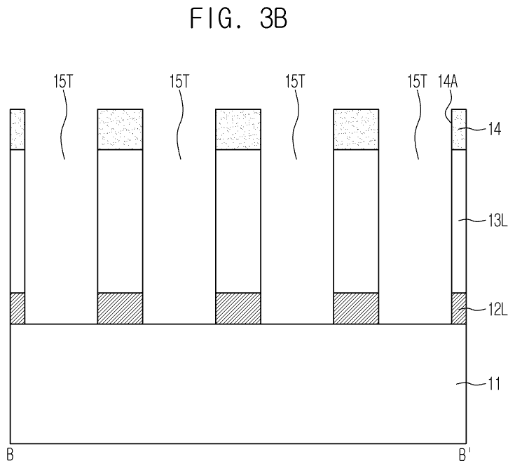

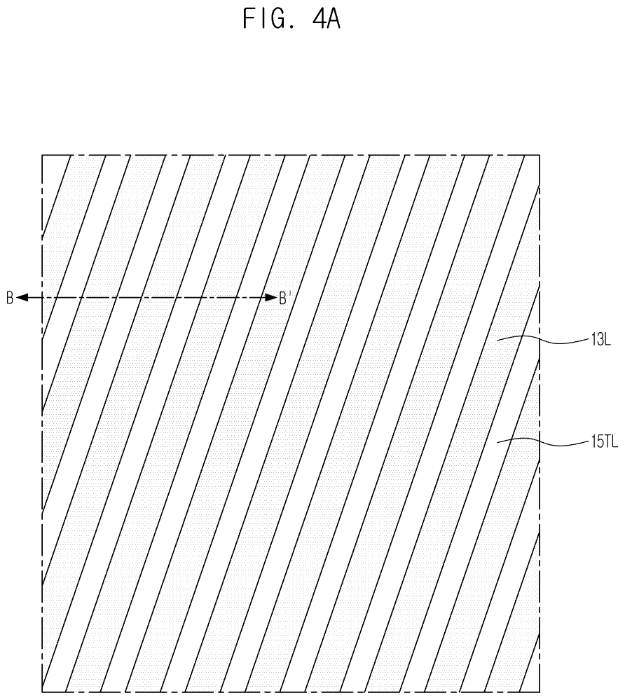

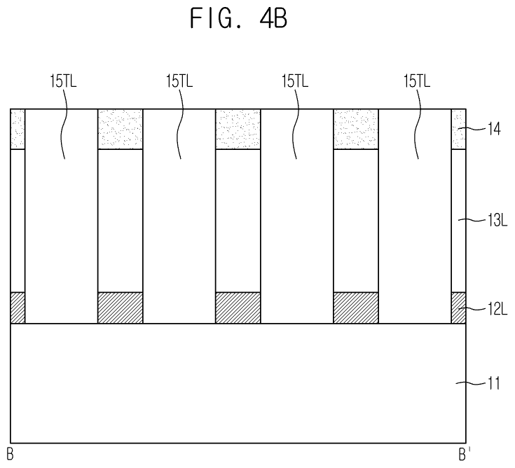

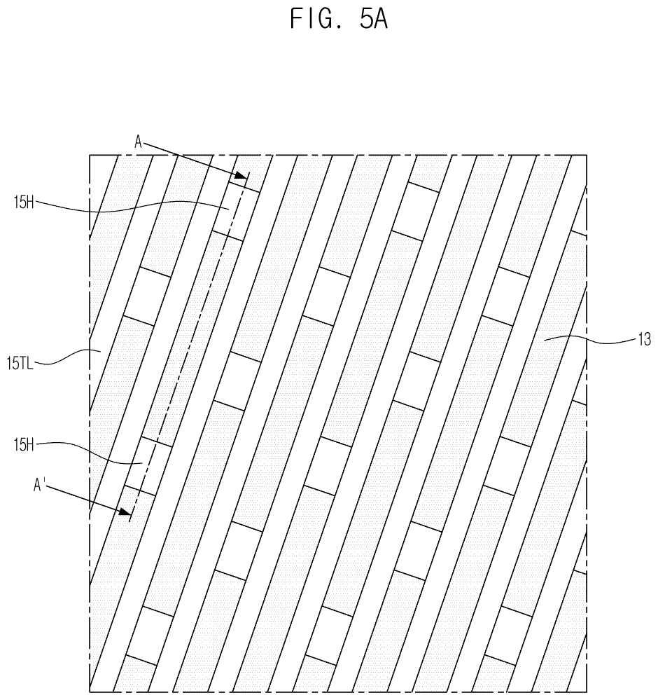

FIG. 3A is a plan view illustrating the semiconductor device to describe a method for forming line-shape openings 15T, and FIG. 3B is a cross-sectional view illustrating the semiconductor device taken along line B-B′ shown in FIG. 3A.

As illustrated in FIGS. 3A and 3B, a hard mask layer 14 may be formed on the active layer 13. The hard mask layer 14 may include a hard mask material or a photoresist. The hard mask layer 14 may include a plurality of hard mask layer-level openings 14A. The hard mask layer-level openings 14A, which are line-shape openings, may extend in one direction. The hard mask layer-level openings 14A of the hard mask layer 14 may be formed by a lithography process. For example, to form the hard mask layer 14 including the hard mask layer-level openings 14A, forming a photoresist pattern on a hard mask material and patterning the hard mask material using the photoresist pattern as an etch barrier may be included. The hard mask layer 14 may be a material having an etch selectivity with respect to the active layer 13 and the buried material layer 12A. The hard mask layer 14 may include silicon oxide, silicon nitride, amorphous carbon, silicon oxynitride, or a combination thereof.

A plurality of line-shape active layers 13L and a plurality of line-shape buried layers 12L may be formed on the substrate 11. The line-shape active layers 13L may be formed by etching the active layer 13A, and the line-shape buried layers 12L may be formed by etching the buried material layer 12A. For example, the active layer 13A may be etched using the hard mask layer 14 as an etch barrier to form the line-shape active layers 13L, and the buried material layer 12A may be etched continuously to form the line-shape buried layers 12L.

The line-shape openings 15T may be formed between neighboring line-shape active layers 13L. The line-shape openings 15T may extend to be disposed between neighboring line-shape buried layers 12L. From the perspective of a top view, the line-shape active layers 13L may be alternately repeated with the line-shape openings 15T.

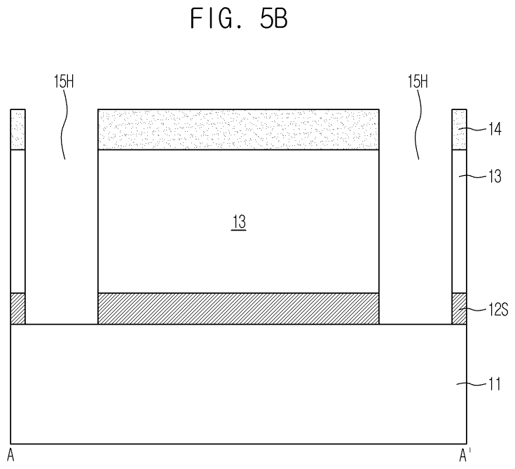

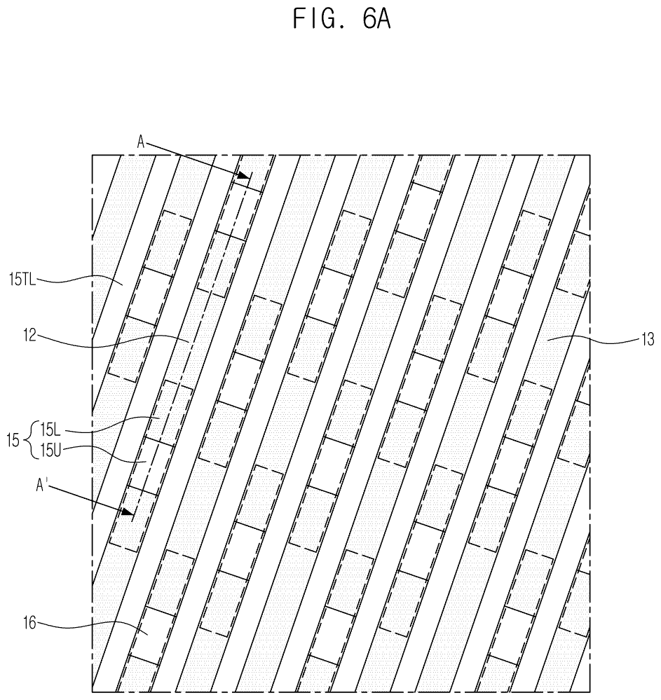

FIG. 4A is a plan view illustrating the semiconductor device to describe a method for forming line-shape isolation layers 15TL, and FIG. 4B is a cross-sectional view illustrating the semiconductor device taken along line B-B′ shown in FIG. 4A.

As illustrated in FIGS. 4A and 4B, the line-shape isolation layers 15TL may be formed in the line-shape openings 15T. The line-shape isolation layers 15TL may correspond to the first isolation structure 102A as described with reference to FIGS. 1A to 1D. Forming the line-shape isolation layers 15TL may include forming a dielectric material filling the line-shape openings 15T and planarizing the dielectric material. The line-shape isolation layers 15TL may each include silicon oxide, silicon nitride, an air gap, or a combination thereof. From the perspective of a top view, the line-shape active layers 13L may be alternately repeated with the line-shape isolation layers 15TL.

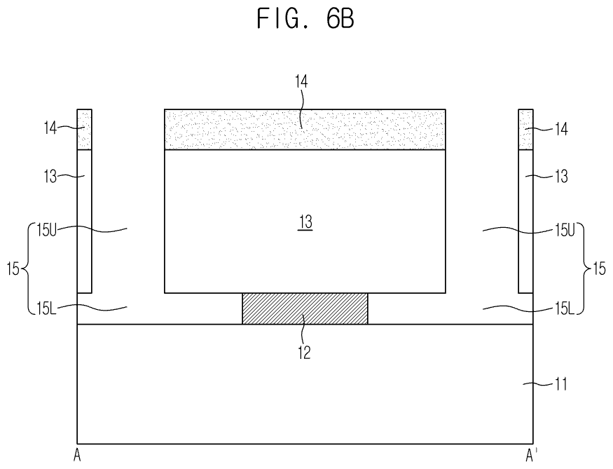

FIG. 5A is a plan view illustrating the semiconductor device to describe a method for forming active regions 13, and FIG. 5B is a cross-sectional view illustrating the semiconductor device taken along line A-A′ shown in FIG. 5A.

As illustrated in FIGS. 5A and 5B, a plurality of active regions 13 and a plurality of buried strip layers 12S may be formed on the substrate 11. The active regions 13 may be formed by etching the line-shape active layers 13L, and the buried strip layers 12S may be formed by etching the line-shape buried layers 12L.

Each of the active regions 13 may be formed between the line-shape isolation layers 15TL, and neighboring active regions 13 may be spaced apart from each other by a hole-shape opening 15H. The line-shape active layers 13L may be etched to form the hole-shape openings 15H, and accordingly, a plurality of active regions 13, which are spaced apart from one another by the hole-shaped openings 15H, may be formed. Each of the active regions 13 may have an island shape. The process of forming the plurality of active regions 13 and the hole-shape openings 15H may be referred to as a cutting process of the line-shape active layers 13L.

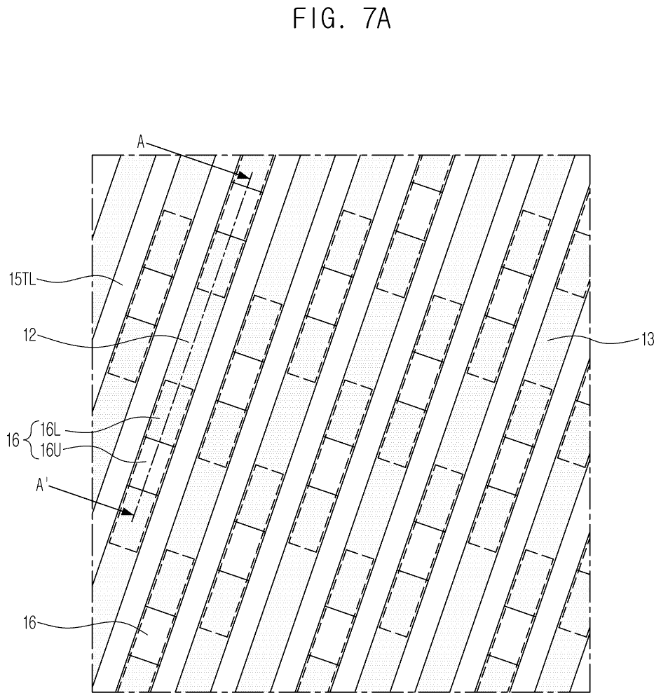

FIG. 6A is a plan view illustrating the semiconductor device to describe a method for forming buried layers 12, and FIG. 6B is a cross-sectional view illustrating the semiconductor device taken along line A-A′ shown in FIG. 6A.

As illustrated in FIGS. 6A and 6B, the buried strip layers 12S may be selectively and horizontally recessed through the hole-shape openings 15H to form the buried layers 12 below the active regions 13. One buried layer 12 may be disposed below one active region 13. A horizontal length of each buried layer 12 may be smaller than that of each active region 13.

After the buried layers 12 are formed, the hole-shape openings 15H may be expanded as indicated by reference numeral “15”. Each of the hole-shape openings 15 may include a vertical opening 15U and a horizontal opening 15L. The vertical opening 15U may be formed between the active regions 13, and the horizontal opening 15L may be formed between the buried layers 12. The horizontal opening 15L may extend from the vertical opening 15U. The horizontal opening 15L may be referred to as an undercut, and the undercut may be disposed between each of the buried layers 12 and each of the active regions 13.

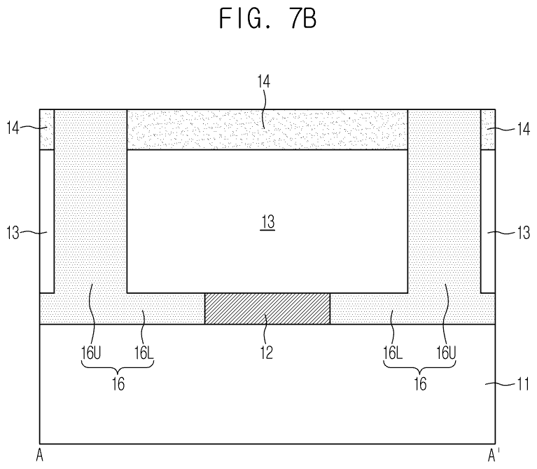

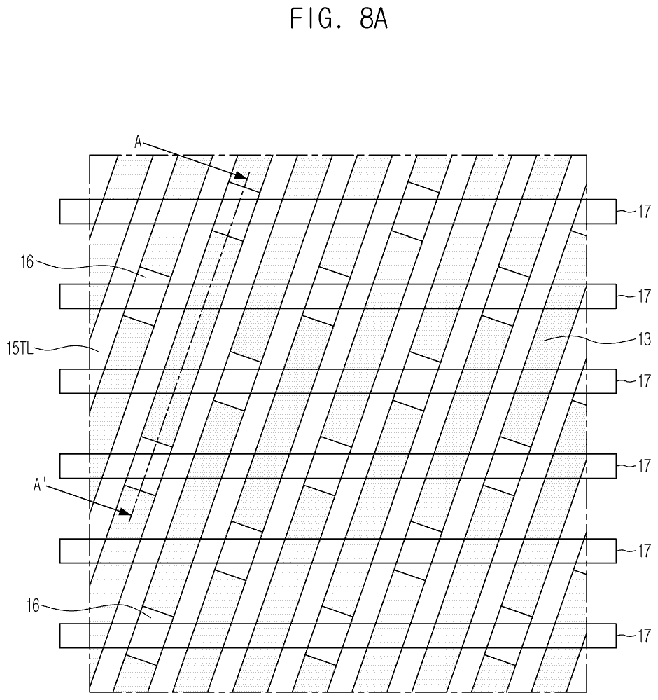

FIG. 7A is a plan view illustrating the semiconductor device to describe a method for forming island-shape isolation layers 16, and FIG. 7B is a cross-sectional view illustrating the semiconductor device taken along line A-A′ shown in FIG. 7A.

As illustrated in FIGS. 7A and 7B, the island-shape isolation layers 16 may be formed to fill the hole-shape openings 15. Each of the island-shape isolation layers 16 may include a pillar isolation portion 16U and a buried isolation portion 16L. The pillar isolation portion 16U may be formed between the active regions 13. The buried isolation portion 16L may be formed between the buried layers 12. The buried isolation portion 16L may extend from the pillar isolation portion 16U. The buried isolation portions 16L may contact the substrate 11. The pillar isolation portions 16U may contact the active regions 13. The island-shape isolation layer 16 may correspond to the second isolation structure 102B as described with reference to FIGS. 1A to 1D. The pillar isolation portion 16U may correspond to the pillar isolation portion 102U as described with reference to FIGS. 1A to 1D, and the buried isolation portion 16L may correspond to the buried isolation portion 102L as described with reference to FIGS. 1A to 1D.

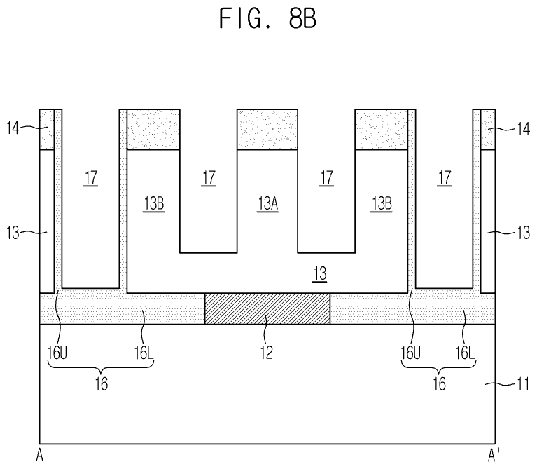

Hereinafter, FIGS. 8A to 11B are cross-sectional views illustrating the semiconductor device taken along line A-A′ shown in FIG. 7A to describe subsequent processes.

As illustrated in FIGS. 8A and 8B, a gate trench 17 may be formed in the active region 13. The gate trench 17 may be formed to have a line shape crossing the active region 13 and the line-shape isolation layer 15TL. The gate trench 17 may be formed by an etch process of the active region 13, using the hard mask layer 14 as an etch mask. The gate trench 17 may be formed shallower than the island-shape isolation layer 16.

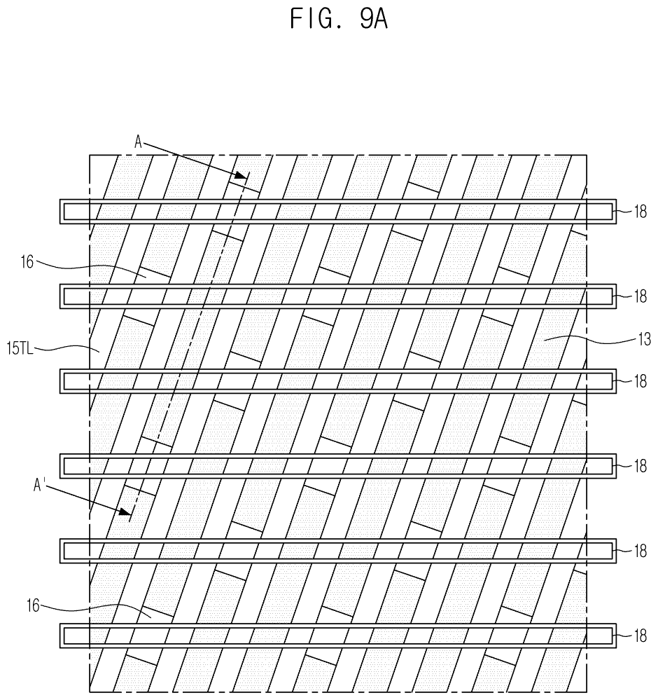

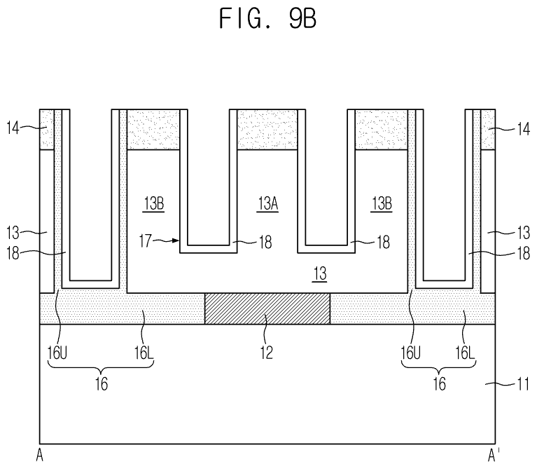

As illustrated in FIGS. 9A and 9B, a gate dielectric layer 18 may be formed on the gate trench 17. Before the gate dielectric layer 18 is formed, etch damage on a surface of the gate trench 17 may be healed. For example, after sacrificial oxide is formed by thermal oxidation treatment, the sacrificial oxide may be removed. The gate dielectric layer 18 may be formed by a thermal oxidation process. The gate dielectric layer 18 may include silicon oxide. In another embodiment, the gate dielectric layer 18 may be formed by chemical vapor deposition (CVD) or atomic layer deposition (ALD). The gate dielectric layer 18 may include a high-k material, oxide, nitride, oxide nitride, or a combination thereof. The high-k material may include a hafnium-containing material. The hafnium-containing material may include hafnium oxide, hafnium silicon oxide, hafnium silicon oxynitride, or a combination thereof. In another embodiment, the high-k material may include lanthanum oxide, lanthanum aluminum oxide, zirconium oxide, zirconium silicon oxide, zirconium silicon oxynitride, aluminum oxide, or a combination thereof. As the high-k material, other publicly-known high-k materials may also be selectively used. In another embodiment, the gate dielectric layer 18 may include a stack of silicon oxide and a high-k material. The high-k material may include a material having a higher areal density of oxygen atom than the silicon oxide.

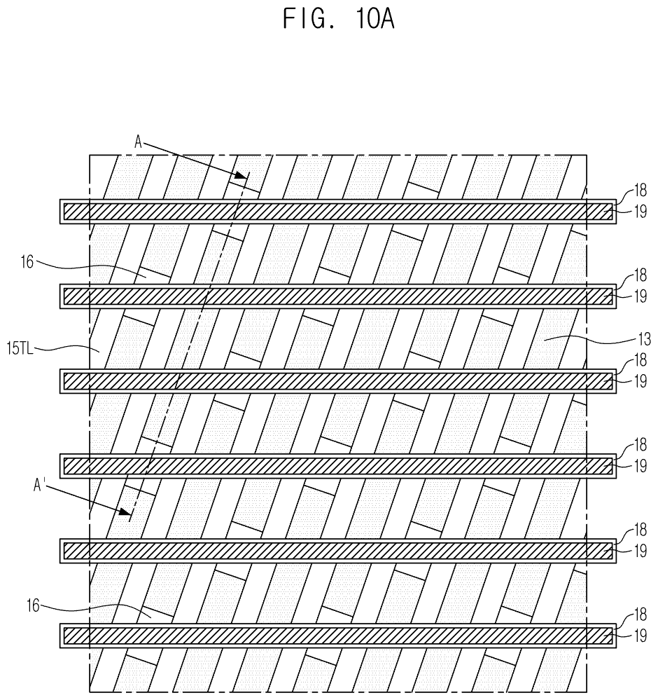

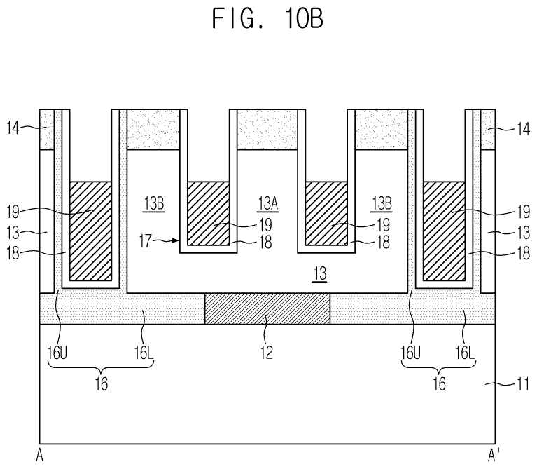

As illustrated in FIGS. 10A and 10B, a gate electrode 19 may be formed on the gate dielectric layer 18 to partially fill the gate trench 17. The gate electrode 19 may be disposed at a level lower than the top of the active region 13. The gate electrode 19 may include a metal, a metal-based material such as, for example, metal nitride, a semiconductor material or a combination thereof. The gate electrode 19 may include polysilicon, tantalum nitride (TaN), titanium nitride (TIN), tungsten (W), tungsten nitride (WN), molybdenum (Mo), ruthenium (Ru), or a combination thereof. The gate electrode 19 may be formed by a stack of titanium nitride and tungsten, a stack of titanium nitride and polysilicon, or titanium nitride only. In another embodiment, the gate electrode 19 may have a high work function. The high work function refers to a work function higher than a mid-gap work function of silicon. A low work function refers to a work function lower than the mid-gap work function of silicon. Specifically, the high work function may have a work function higher than 4.5 eV, and the low work function may have a work function lower than 4.5 eV. The gate electrode 19 may include P-type polysilicon or nitrogen-rich titanium nitride (TiN).

In another embodiment, the gate electrode 19 may have an increased high work function. The gate electrode 19 may include metal silicon nitride. The metal silicon nitride may be metal nitride doped with silicon. The gate electrode 19 may include metal silicon nitride having an adjusted atomic percent of silicon. For example, the gate electrode 19 may include tantalum silicon nitride (TaSiN) or titanium silicon nitride (TiSiN). Titanium nitride may have a high work function, and contain silicon to further increase the work function thereof. The titanium silicon nitride may have an adjusted atomic percent of silicon, so as to have an increased high work function. In another embodiment, the gate electrode 19 may include titanium aluminum nitride (TiAlN).

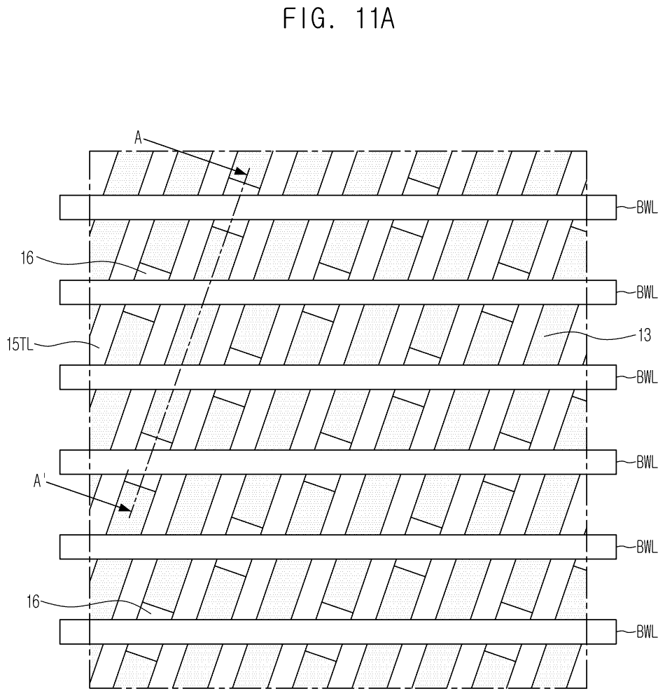

As illustrated in FIG. 11A and FIG. 11B, a capping layer 20 may be formed on the gate electrode 19. The capping layer 20 may serve to protect the gate electrode 19. The capping layer 20 may fill an upper portion of the gate trench 16 on the gate electrode 19. A top surface of the capping layer 20 may be disposed at the same level as a top surface of the hard mask layer 14. The capping layer 20 may include silicon oxide, silicon nitride, or a combination thereof. In another embodiment, the capping layer 20 may include fluorine-containing silicon oxide, fluorine-containing silicon nitride, or a combination thereof.

Thus, as described above, a buried gate structure BWL may be formed in the gate trench 17 including the gate dielectric layer 18, the gate electrode 19, and the capping layer 20.

First and second doped regions 21 and 22 may be formed in the active region 13. The first and second doped regions 21 and 22 may be referred to as source/drain regions. The first and second doped regions 21 and 22 may be regions doped with conductive dopants. For example, the conductive dopants may include phosphorus (P), arsenic (As), antimony (Sb), or boron (B). The first and second doped regions 21 and 22 may be doped with the same conductive type of dopants. The first and second doped regions 21 and 22 may be disposed in the active region 13 on both sides of the gate trench 17. The bottom surfaces of the first and second doped regions 21 and 22 may be disposed at a predetermined depth from the top surface of the active region 13. The first and second doped regions 21 and 22 may be disposed at the same depth. In another embodiment, the first and second doped regions 21 and 22 may be disposed at different depths. The first doped region 21 may be referred to as a “first source/drain region” and the second doped region 22 may be referred to as a “second source/drain region”. A channel may be defined between the first doped region 21 and the second doped region 22 by the gate electrode 19. The channel may be defined along the profile of the gate trench 17.

Subsequently, as illustrated with reference to FIG. 1B, a first contact node 121, a bit line 120, a second contact node 131, and a data storage element 130 may be formed. For example, forming the first contact node 121 and bit line 120 connected to the first doped region 21 and forming the second contact node 131 and data storage element 130 connected to the second doped region 22 may be performed.

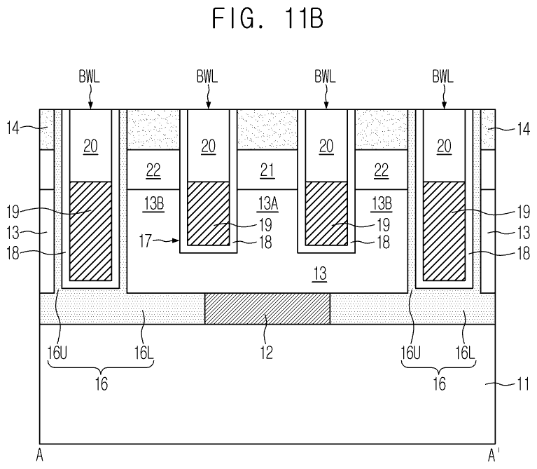

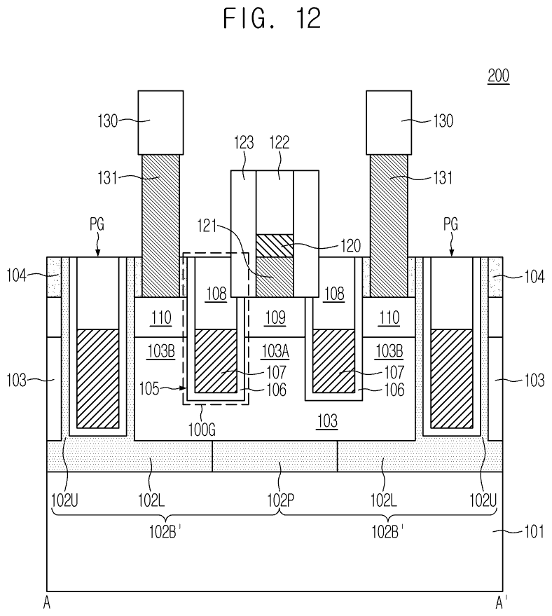

FIG. 12 is a view illustrating a semiconductor device 200 in accordance with another embodiment of the present disclosure.

Referring to FIGS. 1A, 1B, 1C, 1D, 1E and 12, the semiconductor device 200 may be similar to the semiconductor device 100 as illustrated with reference to FIGS. 1A to 1E. Hereinafter, detailed descriptions of overlapping components are provided with reference to FIGS. 1A to 1E.

The semiconductor device 200 may include a substrate 101, an isolation structure 102, an active region 103, and a gate structure 100G.

The active region 103 may be formed on the substrate 101. The substrate 101 and the active region 103 may each include a semiconductor material. The substrate 101 and the active region 103 may be the same semiconductor material.

The active region 103 may be defined by the isolation structure 102. The isolation structure 102 may include first isolation structures (reference numeral “102A” of FIG. 1A) and second isolation structures 102B′. The first isolation structures 102A may each have a line shape, and the second isolation structures 102B′ may each have a pillar shape. The first and second isolation structures 102A and 102B′ may each include a dielectric material. The first and second isolation structures 102A and 102B′ may each include a dielectric material including silicon oxide, silicon nitride and an embedded air gap, or a combination thereof.

Each of the second isolation structures 102B′ may include a buried isolation portion 102L, a pillar isolation portion 102U, and a bridge portion 102P between the buried isolation portion 102L and the pillar isolation portion 102U. The buried isolation portion 102L may extend horizontally from a bottom surface of the pillar isolation portion 102U, and the bridge portion 102P may extend horizontally from the buried isolation portion 102L. The pillar isolation portion 102U, the buried isolation portion 102L, and the bridge portion 102P, which are formed of the same material, may each have an integral structure. The second isolation structure 102B′ may have a “IL” shape by a combination of the pillar isolation portion 102U, the buried isolation portion 102L and the bridge portion 102P. The pillar isolation portion 102U, the buried isolation portion 102L and the bridge portion 102P may each include a dielectric material including silicon oxide, silicon nitride, an air gap and an embedded air gap, or a combination thereof.

As described with reference to FIGS. 1C and 1D, the active region 103 may include a plurality of side wall facets F1 to F4 and a bottom surface BS. The side wall facets F1 to F4 may include first side wall facets F1 and F2 and second side wall facets F3 and F4. The first side wall facets F1 and F2 may contact the first isolation structures 102A. The second side wall facets F3 and F4 may contact the second isolation structures 102B′. The surface area of the first side wall facets F1 and F2 may be larger than that of the second side wall facets F3 and F4. The bottom surface BS of the active region 103 may contact the second isolation structures 102B′. The bottom surface BS of the active region 103 may contact the buried isolation portion 102L and bridge portion 102P of the second isolation structures 102B′.

Gate trenches 105 may be formed in the active region 103. The gate trenches 105 may each have a line-shape extending in one direction. The gate trenches 105 may each have a line shape crossing the active region 103 and the first isolation structure 102A. The gate trenches 105 and the bridge portion 102P may be spaced apart from each other. In another embodiment, bottom surfaces of the gate trenches 105 may each have a curvature.

Two gate trenches 105 may be disposed in one active region 103. A portion of the active region 103 may be divided into one first active node 103A and two second active nodes 103B by the gate trenches 105. The first active node 103A may be disposed between two second active nodes 103B. The buried isolation portions 102L of the second isolation structures 102B′ may be disposed below the second active nodes 103B. The bridge portion 102P may be disposed below the first active node 103A.

A first doped region 109 and a second doped region 110 may be formed in the active region 103.

The buried gate structure 100G may include a gate dielectric layer 106 covering the bottom surface and side walls of the trench 105, a gate electrode 107 partially filling the trench 105 on the gate dielectric layer 106, and a capping layer 108 on the gate electrode 107. A combination of the gate electrode 107, the first doped region 109 and the second doped region 110 may constitute a cell transistor.

The gate electrode 107 may be a buried gate electrode that partially fills the gate trench 105. The gate electrode 107 may be disposed at a level lower than a top surface of the active region 103, i.e., top surfaces of the first and second doped regions 109 and 110.

The capping layer 108 may serve to protect the gate electrode 107. The capping layer 108 may be disposed on the gate electrode 107 to fill an upper portion of the trench 105. A top surface of the capping layer 108 may be disposed at the same level as the top surfaces of the first and second doped regions 109 land 110.

A bit line 120 may be electrically connected to the first doped region 109. For example, the bit line 120 may be connected to the first doped region 109 through a first contact node 121. A data storage element 130 may be electrically connected to the second doped region 110. For example, the data storage element 130 may be connected to the second doped region 110 through a second contact node 131.

A bit line hard mask layer 122 may be formed on the bit line 120, and a bit line spacer 123 may be formed on a side wall of the bit line 120.

The data storage element 130 may include a memory element such as a capacitor.

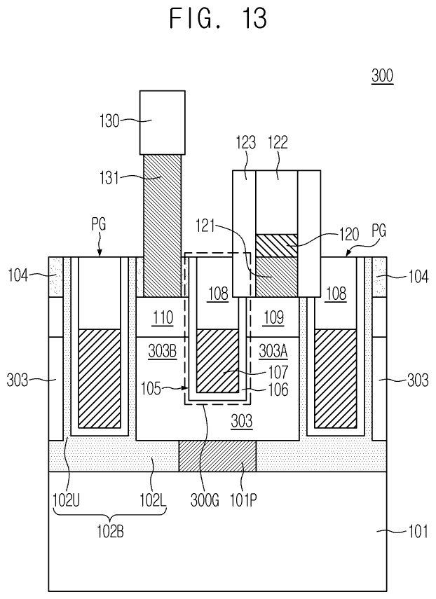

FIG. 13 is a view illustrating a semiconductor device 300 in accordance with another embodiment of the present disclosure.

Referring to FIGS. 1A, 1B, 1C, 1D, 1E and 13, the semiconductor device 300 may be similar to the semiconductor device 100 as illustrated with reference to FIGS. 1A to 1E. Hereinafter, detailed descriptions of overlapping components are provided with reference to FIGS. 1A to 1E.

The semiconductor device 300 may include a substrate 101, a second isolation structure 102B, an active region 303, a buried layer 101P between the substrate 101 and the active region 303, and a buried gate structure 300G.

The active region 303 may be formed on the substrate 101. The buried layer 101P may be disposed between the substrate 101 and the active region 303. The substrate 101, the buried layer 101P and the active region 303 may each include a semiconductor material. The substrate 101 and the active region 303 may be the same semiconductor material. The buried layer 101P and the substrate 101 may be different semiconductor materials. The buried layer 101P and the active region 303 may be different semiconductor materials.

The substrate 101 may be a material suitable for semiconductor processing. The substrate 101 may include a semiconductor substrate. The substrate 101 may be formed of a material containing silicon. The substrate 101 and the active region 303 may each include silicon, monocrystalline silicon, polysilicon, amorphous silicon, carbon-doped silicon, a combination thereof, or a multilayer thereof. The buried layer 101P may be a material having an etch selectivity with respect to the substrate 101 and the active region 303. The buried layer 101P may include germanium-containing silicon, boron-containing silicon, or a combination thereof. The buried layer 101P may include silicon germanium (SiGe) or silicon boron nitride (SiBN). The buried layer 101P and the active region 303 may be formed by epitaxial growth on the substrate 101. In another embodiment, the active region 303 may include an oxide semiconductor material such as IGZO (InGaZnO).

A horizontal length of the active region 303 may be greater than that of the buried layer 101P.

The active region 303 may be defined by the second isolation structure 102B. As described with reference to FIG. 1A, the second isolation structure 102B is a portion of the isolation structure 102, and the isolation structure 102 may include first isolation structures 102A and second isolation structures 102B. The first isolation structures 102A may each have a line shape, and the second isolation structures 102B may each have a pillar shape. The first and second isolation structures 102A and 102B may each include a dielectric material including silicon oxide, silicon nitride, and an embedded air gap, or a combination thereof.

Each of the second isolation structures 102B may include a buried isolation portion 102L and a pillar isolation portion 102U. The buried isolation portion 102L may extend horizontally from a bottom surface of the pillar isolation portion 102U. The pillar isolation portion 102U and the buried isolation portion 102L may be the same material and have an integral structure. The second isolation structure 102B may have a “L” shape by a combination of the pillar isolation portion 102U and the buried isolation portion 102L. The pillar isolation portion 102U and the buried isolation portion 102L may each include a dielectric material including silicon oxide, silicon nitride, an air gap, and an embedded air gap, or a combination thereof.

A bottom surface of the active region 303 may contact the second isolation structures 102B. The bottom surface of the active region 303 may contact the buried isolation portions 102L of the second isolation structures 102B. The buried isolation portions 102L may contact the buried layer 101P.

A gate trench 105 may be formed in the active region 303. The gate trench 105 may have a line shape extending in one direction. The gate trench 105 may have a line shape crossing the active region 303 and the first isolation structure 102A. The gate trench 105 and the buried layer 101P may be spaced apart from each other. In another embodiment, a bottom surface of the gate trench 105 may have a curvature.

One gate trench 105 may be disposed in one active region 303. A portion of the active region 303 may be divided into one first active node 303A and one second active node 303B by the gate trench 105.

A first doped region 109 and a second doped region 110 may be formed in the active region 303.

The buried gate structure 300G may include a gate dielectric layer 106 covering the bottom surface and side walls of the gate trench 105, a gate electrode 107 disposed on the gate dielectric layer 106 and partially filling the gate trench 105, and a capping layer 108 disposed on the gate electrode 107. A combination of the gate electrode 107, the first doped region 109 and the second doped region 110 may constitute a cell transistor.

A bit line 120 may be electrically connected to the first doped region 109. For example, the bit line 120 may be connected to the first doped region 109 through a first contact node 121. A data storage element 130 may be electrically connected to the second doped region 110, for example, through a second contact node 131. The first contact node 121 may be referred to as a “bit line contact plug”, and the second contact node 131 may be referred to as a “storage contact plug”.

Referring to FIG. 13, the semiconductor device 300 may include a plurality of memory cells, and neighboring memory cells may be isolated from each other by the isolation structure 102. One memory cell may be formed on one active region 303. Each memory cell may have one gate electrode 107 formed in one active region 303, which may be referred to as a “one gate-one active (1G1A) structured memory cell”. In the 1G1A structured memory cell, the bit line 120 is connected to one active region 303, so that one memory cell may be connected to one bit line 120. The 1G1A structured memory cell may include one transistor-one capacitor (1T1C). As a comparative example, in a general DRAM, two memory cells are formed in one active region, two gate electrodes are formed in one active region, and two neighboring memory cells share one bit line.

The semiconductor device 300 including the 1G1A structured memory cell may have active regions 303 disposed in a single direction also referred to as a uni-direction. The isolation structure 102, the second active node 303B, the gate electrode 107, the first active node 303A, and the isolation structure 102 may be sequentially disposed in the uni-direction.

According to various embodiments of the present disclosure, leaning of an active region may be prevented by a hybrid isolation structure even though the aspect ratio of the active region increases in response to high integration of a semiconductor device.

While the present disclosure has been illustrated and described with respect to specific embodiments and drawings, the disclosed embodiments are not intended to be restrictive. Further, it is noted that the present disclosure may be achieved in various ways through substitution, change, and modification, as those skilled in the art will recognize in light of the present disclosure, without departing from the spirit and/or scope of the present disclosure and the following claims.

What is claimed is:

1. A semiconductor device comprising:
a substrate;
an active region disposed over the substrate;
a buried layer disposed between the substrate and the active region; and
an isolation structure surrounding a bottom surface and side surfaces of the active region and surrounding side surfaces of the buried layer.

2. The semiconductor device of claim 1, wherein the buried layer has a smaller size than the active region.

3. The semiconductor device of claim 1, wherein the buried layer includes a material having a selectivity with respect to the substrate and the active region.

4. The semiconductor device of claim 1, wherein the substrate and the active region each include a first semiconductor material, and the buried layer includes a second semiconductor material, and the first semiconductor material and the second semiconductor material are different materials.

5. The semiconductor device of claim 1, wherein the substrate and the active region each include silicon, and the buried layer includes silicon germanium.

6. The semiconductor device of claim 1, wherein the isolation structure includes:
a first isolation structure having a line shape; and
a second isolation structure having a pillar shape that contacts the first isolation structure.

7. The semiconductor device of claim 6, wherein the second isolation structure includes:
a pillar isolation portion; and
a buried isolation portion extending horizontally from the pillar isolation portion,
wherein the buried isolation portion has a shape surrounding the side surfaces of the buried layer.

8. The semiconductor device of claim 1, wherein the isolation structure includes a dielectric material.

9. A semiconductor device comprising:
a substrate;
an active region disposed over the substrate;
a buried layer disposed between the substrate and the active region;
an isolation structure surrounding a bottom surface and side surfaces of the active region and surrounding side surfaces of the buried layer;
a gate trench formed in the active region;
a gate dielectric layer formed on the gate trench; and
a gate electrode disposed on the gate dielectric layer and partially filling the gate trench.

10. The semiconductor device of claim 9, further comprising a passing gate formed in the isolation structure.

11. The semiconductor device of claim 9, wherein the substrate and the active region each include a first semiconductor material, and the buried layer includes a second semiconductor material, and the first semiconductor material and the second semiconductor material are different materials.

12. The semiconductor device of claim 9, wherein the substrate and the active region each include silicon, and the buried layer includes silicon germanium.

13. The semiconductor device of claim 9, wherein the isolation structure includes:
a first isolation structure having a line shape; and
a second isolation structure having a pillar shape that contacts the first isolation structure.

14. The semiconductor device of claim 13, wherein the second isolation structure includes:
a pillar isolation portion; and
a buried isolation portion extending horizontally from the pillar isolation portion,
wherein the buried isolation portion has a shape surrounding the side surfaces of the buried layer.

15. The semiconductor device of claim 9, wherein the isolation structure includes a dielectric material.

16. A method for fabricating a semiconductor device, comprising:
stacking a buried material layer and an active layer on a substrate;
etching the active layer and forming line-shape openings and a line-shape active layer;
etching the buried material layer below the line-shape openings and forming a line-shape buried layer;
forming line-shape isolation layers that fill the line-shape openings;
etching the line-shape active layer and forming an active region and hole-shape openings;
forming undercuts between the active region and the substrate while forming a buried layer by etching the line-shape buried layer from the hole-shape openings; and
forming pillar-shape isolation layers that fill the undercuts and the hole-shape openings.

17. The method of claim 16, wherein the substrate and the active region each include a first semiconductor material, wherein the buried layer includes a second semiconductor material, and wherein the first semiconductor material and the second semiconductor material are different materials.

18. The method of claim 16, wherein the substrate and the active region each include silicon, and the buried layer includes silicon germanium.

19. The method of claim 16, wherein each of the pillar-shape isolation layers includes:
a pillar isolation portion; and
a buried isolation portion extending horizontally from the pillar isolation portion,
wherein the buried isolation portion has a shape filling the undercuts.

20. The method of claim 16, wherein the buried layer includes a dielectric material.
